(19) United States
(12) Patent Application Publication
(10) Pub. No.: US 2011/0109955 A1
(43) Pub. Date: May 12, 2011

(54) ELECTRO-OPTIC DEVICE

(75) Inventors: Jeong Woo PARK, Daejeon (KR); Jongbum You, Seongnam (KR); Gyungock Kim, Seoul (KR)

(73) Assignee: Electronics and Telecommunications Research Institute, Daejeon (KR)

(21) Appl. No.: 12/771,939

(22) Filed: Apr. 30, 2010

(30) Foreign Application Priority Data
Nov. 6, 2009 (KR) 10-2009-0107081

(51) Int. Cl. G02F 1/015; H01L 33/00

(52) U.S. Cl. 359/279; 359/245; 257/80; 257/E33.076

(57) ABSTRACT

Provided is an electro-optic device. Sine the electro-optic device includes a plurality of first conductive type semiconductor layers and a plurality of depletion layers formed by a third semiconductor disposed between the plurality of first conductive type semiconductor layers, an electro-optic device optimized for a high speed and low power consumption can be provided.

### CROSS-REFERENCE TO RELATED APPLICATIONS

This U.S. non-provisional patent application claims priority under 35 U.S.C. §119 of Korean Patent Application No. 10-2009-0107081, filed on Nov. 6, 2009, the entire contents of which are hereby incorporated by reference.

### BACKGROUND OF THE INVENTION

The present invention disclosed herein relates to an electro-optic device, and more particularly, to an electro-optic device including a plurality of depletion layers.

As semiconductor industries have been highly developed, semiconductor integrated circuits such as logic devices and memory devices are becoming more high speed and high integration. With the high speed and high integration of the semiconductor integrated circuits, a transmission speed between the semiconductor integrated circuits are directly linked with performance of electronic devices including the semiconductor integrated circuits. Typically, semiconductor integrated circuits receive/transmit data through electrical communication electrically receiving/transmitting data. For example, semiconductor integrated circuits are mounted on a printed circuit board (PCB) to electrically communicate with each other through interconnections disposed in the PCB.

In this case, there is a limitation to reduce an electrical resistance (e.g., a resistance between a pad of a semiconductor integrated circuit and an external terminal of a package, a contact resistance between a package and a PCB, and/or an interconnection resistance of a PCB) between the semiconductor integrated circuits. Also, the electrical communication may be affected by external electromagnetic waves. Due to these effects, it is difficult to increase the transmission speed between the semiconductor integrated circuits. With the tendency of high integration and high speed of the semiconductor devices, researches in which optical signals are used to increase the transmission speed between semiconductor chips are being conducted.

### SUMMARY OF THE INVENTION

The present invention provides an electro-optic device having an improved operation speed.

The present invention also provides an electro-optic device optimized for a high integration.

The present invention also provides an electro-optic device optimized for low power consumption.

Embodiments of the present invention provide electro-optic devices including: a substrate; a optical modulator disposed on the substrate, the optical modulator including a first conductive type first semiconductor, a first conductive type second semiconductor, and a second conductive type third semiconductor disposed between the first semiconductor and the second semiconductor; and first and second recesses connected to both sidewalls of the optical modulator, the first and second recesses having top surfaces lower than a top surface of the optical modulator, wherein the optical modulator includes a first depletion layer formed by a junction of the first semiconductor and the third semiconductor and a second depletion layer formed by a junction of the second semiconductor and the third semiconductor, and the first conductive type and the second conductive type are different from each other.

In some embodiments, a reverse bias voltage may be applied to any one of the first and second depletion layers during the operation.

In other embodiments, the first recess and the second recess may include a first high concentration doped region and a second high concentration doped region, which have a concentration greater than those of the first semiconductor and the second semiconductor, respectively, and the reverse bias voltage may be generated by a voltage applied between the first high concentration doped region and the second high concentration doped region during the operation.

In still other embodiments, the first high concentration doped region and the second high concentration doped region may be laterally spaced from both sidewalls of the optical modulator.

In even other embodiments, the optical modulator may have a light receiving surface through which a first optical signal is incident and a light emission surface through which a second optical signal is emitted, wherein a phase of the second optical signal may be adjusted by the reverse bias voltage difference.

In yet other embodiments, electro-optic devices may further include a grating coupler connected to any one of the light receiving surface and the light emission surface of the optical modulator.

In further embodiments, a light absorption of the optical modulator may be adjusted by the reverse bias voltage difference.

In still further embodiments, electro-optic devices may further include an oxide layer disposed between the substrate and the optical modulator.

In even further embodiments, the oxide layer may be formed by selectively injecting oxygen ions into a portion at which an optical waveguide is formed on the substrate.

In yet further embodiments, the substrate may have a peripheral region laterally spaced from an electro-optic region in which the optical modulator is disposed, wherein the electro-optic device may further include: a gate dielectric in the peripheral region of the substrate; and a gate electrode disposed on the gate dielectric.

In much further embodiments, a first junction surface between the first semiconductor and the third semiconductor and a second junction surface between the second semiconductor and the third semiconductor may be non-parallel to a top surface of the substrate.

In still much further embodiments, the optical modulator may have a first sidewall and a second sidewall, which face each other, wherein the junction surfaces may be perpendicular to the top surface of the substrate, and a distance between any one of the junction surfaces and the first sidewall may be equal to that between any one of the junction surfaces and the second sidewall.

In even much further embodiments, a reverse bias voltage may be applied between the semiconductors, which form the any one junction surface, during the operation.

In yet much further embodiments, the first semiconductor, the second semiconductor, and the third semiconductor may be sequentially stacked on the substrate, and a first junction surface between the first semiconductor and the third semiconductor and a second junction surface between the second semiconductor and the third semiconductor may be parallel to a top surface of the substrate.

In yet much further embodiments, the optical modulator may further include the first conductive type high concentration doped region disposed on the second semiconductor and having a concentration greater than that of the second semiconductor.

In yet much further embodiments, the optical modulator may have a top surface and a bottom surface, wherein a distance between any one of the junction surfaces and the top surface may be equal to that between any one of the junction surfaces and the bottom surface.

In yet much further embodiments, a reverse bias voltage may be applied between the semiconductors, which form the any one junction surface, during the operation.

In other embodiments of the present invention, electro-optic device include: an input Y-branch including an input terminal, a first optical waveguide connected to the input terminal, and a second optical waveguide spaced from the first optical waveguide and connected to the input terminal; and an output Y-branch including the first optical waveguide, the second optical waveguide, and an output terminal connected to the first optical waveguide and the second optical waveguide, wherein at least one of the first optical waveguide and the second optical waveguide includes: a substrate; a optical modulator disposed on the substrate, the optical modulator including a first conductive type first semiconductor, a first conductive type second semiconductor, and a second conductive type third semiconductor disposed between the first semiconductor and the second semiconductor; and first and second recesses connected to both sidewalls of the optical modulator, the first and second recesses having top surfaces lower than a top surface of the optical modulator, wherein the optical modulator includes a first depletion layer formed by a junction of the first semiconductor and the third semiconductor and a second depletion layer formed by a junction of the second semiconductor and the third semiconductor, and the first conductive type and the second conductive type are different from each other.

In some embodiments, a difference between phases of an input optical signal inputted into the input terminal and an output optical signal outputted from the output terminal may be adjusted by a thickness variation of any one depletion layer of the first depletion layer and the second depletion layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a plan view for explaining an electro-optic device according to an embodiment of the present invention;

FIGS. 2A through 2C are sectional views for explaining an electro-optic device according to an embodiment of the present invention;

FIG. 3 is a sectional view for explaining an electro-optic device according to an embodiment of the present invention;

FIGS. 4A and 4B are sectional views for explaining an electro-optic device according to another embodiment of the present invention;

FIG. 5 is a view illustrating an application example of the electro-optic device according to the embodiments of the present invention; and

FIG. 6 is a graph illustrating a variation characteristic of a depletion capacitance of the optical modulator according to the embodiments of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

Hereinafter, an electro-optic device according to an embodiment of the present invention will be described.

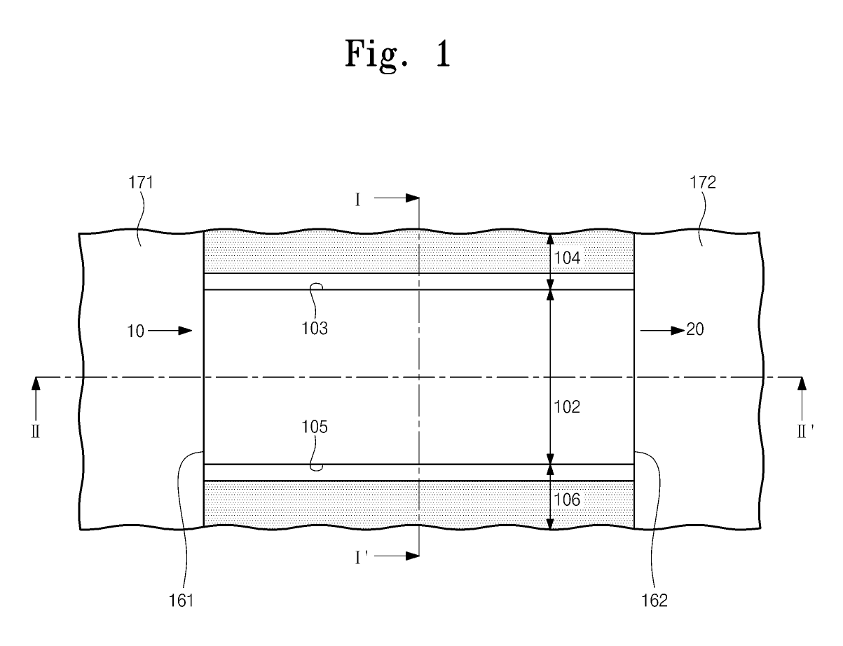

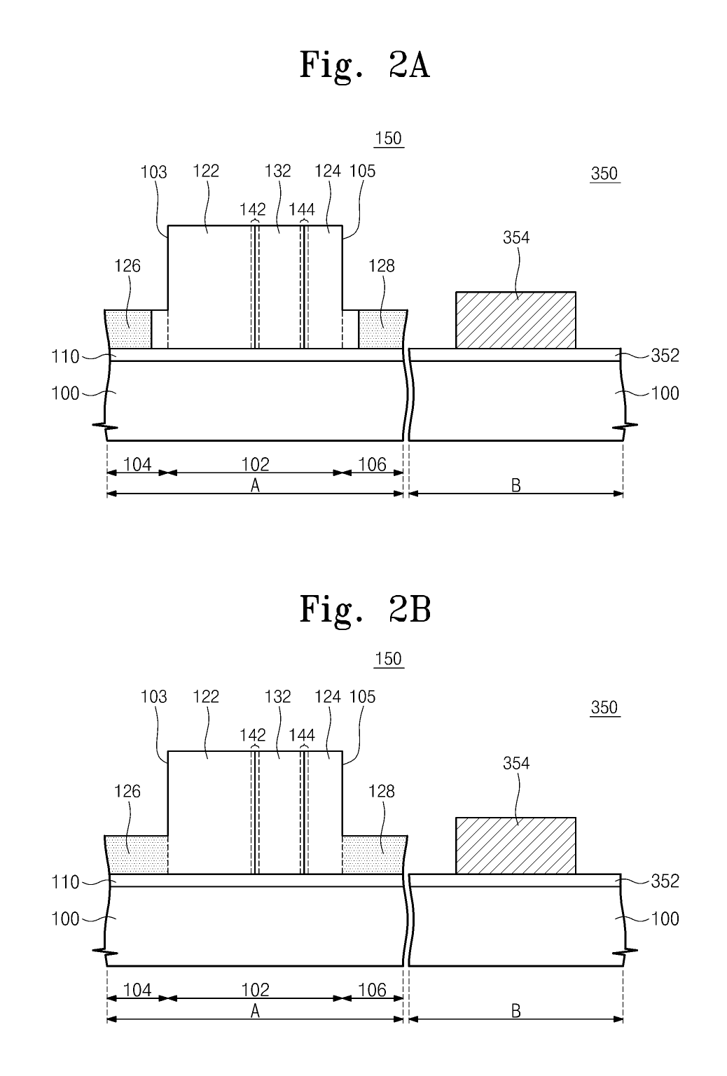

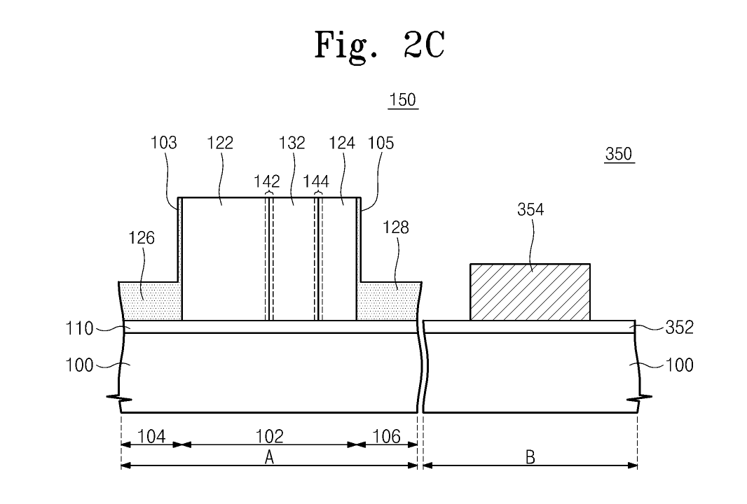

FIG. 1 is a plan view for explaining an electro-optic device according to an embodiment of the present invention. A sectional view taken along line I-I′ of FIG. 1 illustrates an electro-optic region A of FIG. 2A, and a peripheral region B of FIG. 2A may be a peripheral circuit region spaced from the electro-optic region A.

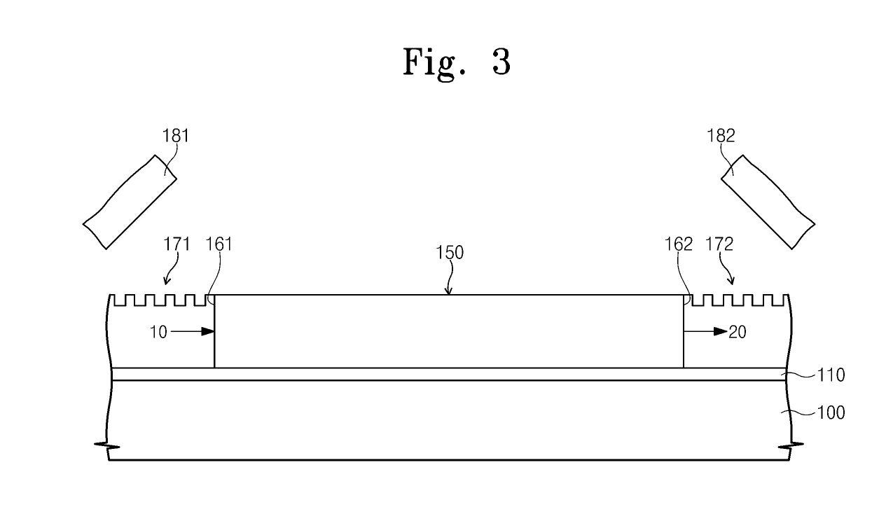

FIG. 3 is a sectional view taken along line II-IF of FIG. 1.

Referring to FIGS. 1, 2A, and 3, a substrate 100 is prepared. The substrate 100 may include a silicon substrate or a silicon-on-insulator (SOI) substrate.

The substrate 100 may include an electro-optic region A and a peripheral region B. An electro-optic device 150 may be disposed in the electro-optic region A. A semiconductor device 350 may be disposed in the peripheral region B.

The electro-optic region A according to an embodiment of the present invention will now be described.

The electro-optic device 150 may be disposed on the substrate 100 of the electro-optic region A. The electro-optic device 150 may extend in a first direction on the substrate 100. The first direction may be parallel to a top surface of the substrate 100. The electro-optic device 150 may include optical modulator 102 and first and second recesses 104 and 106 connected to both sidewalls of the optical modulator 102. The optical modulator 102 may include a first sidewall 103 and a second sidewall 105, which face each other. The first recess 104 may be connected to the first sidewall 103, and the second recess 106 may be connected to the second sidewall 105. The optical modulator 102 may have a flat top surface. The top surface of the optical modulator 102 may be parallel to the top surface of the substrate 100. The optical modulator 102 may be a region through which an optical signal passes. The optical signal may proceed in the first direction. The first and second recesses 104 and 106 may have top surfaces lower than that of the optical modulator 102. The optical modulator 102 and the first and second recesses 104 and 106 may contact each other without any boundary therebetween.

The optical modulator 102 may include a first semiconductor 122 disposed on the substrate 100, a second semiconductor 124 disposed on the substrate 100, and a third semiconductor 132 disposed between the first semiconductor 122 and the second semiconductor 124. The first semiconductor 122 and the second semiconductor 124 may be spaced from each other with the third semiconductor 132 therebetween. The first semiconductor 122, the second semiconductor 124, and the third semiconductor 132 may be sequentially arranged on the substrate 100 in a horizontal direction.

A junction surface between the first semiconductor 122 and the third semiconductor 132 may be non-parallel to the top surface of the substrate 100. The junction surface between the first semiconductor 122 and the third semiconductor 132 may be perpendicular to the top surface of the substrate 100. A junction surface between the second semiconductor 124 and the third semiconductor 132 may be non-parallel to the top surface of the substrate 100. The junction surface between the second semiconductor 124 and the third semiconductor 132 may be perpendicular to the top surface of the substrate 100. The junction surface the first semiconductor 122 and the third semiconductor 132 and the junction surface between the second semiconductor 124 and the third semiconductor 132 may cross the top surface of the substrate 100.

The first and second semiconductors 122 and 124 may include regions doped with a first conductive type dopant, respectively. The third semiconductor 132 may include a region doped with a second conductive type dopant different from the first conductive type dopant. The first conductive type and the second conductive type may be different from each other. For example, the first conductive type may be an N-type, and the second conductive type may be a P-type. On the other hand, the first conductive type may be a P-type, and the second conductive type may be an N-type.

First and second depletion layers 142 and 144 may be formed by a junction of the first semiconductor 122 and the third semiconductor 132 and a junction of the second semiconductor 124 and the third semiconductor 132, respectively. The first and second depletion layers 142 and 144 may be respectively formed along the junction surface between the first semiconductor 122 and the third semiconductor 132 and the junction surface between the second semiconductor 124 and the third semiconductor 132. The first and second depletion layers 142 and 144 may be perpendicular to the top surface of the substrate 100.

A width of the first semiconductor 122 included in the optical modulator 102 may be equal to the sum of a width of the third semiconductor 132 and a width of the second semiconductor 124 included in the optical modulator 102. When the junction surfaces between first, second, and third semiconductors 122, 124, and 132 are perpendicular to the top surface of the substrate 100, a distance between the junction surface between the first semiconductor 122 and the third semiconductor 132, which forms the first depletion layer 142, and the first sidewall 103 of the optical modulator 102 may be equal to that between the junction surface between the first semiconductor 122 and the third semiconductor 132 and the second sidewall 105 of the optical modulator 102.

The top surfaces of the first and second recesses 104 and 106 may have the same height. The top surfaces of the first and second recesses 104 and 106 may parallel to the top surfaces of the substrate 100 and the optical modulator 102.

The first recess 104 may include a first high concentration doped region 126. The first high concentration doped region 126 may be a region doped with the first conductive type dopant at a doping concentration greater than that of the first semiconductor 122. The first high concentration doped region 126 and the first semiconductor 122 may be formed of the same material. For example, the first high concentration doped region 126 may be a region in which the first conductive type dopant is doped into the first semiconductor 122 at a high concentration. The first high concentration doped region 126 may be spaced from the optical modulator 102. In this case, a portion of the first recess 104 between the first high concentration doped region 126 and the optical modulator 102 may be a portion at which the first semiconductor 122 extends.

The second recess 106 may include a second high concentration doped region 128. The second high concentration doped region 128 may be a region doped with the second conductive type dopant at a doping concentration greater than that of the second semiconductor 124. The second high concentration doped region 128 and the second semiconductor 124 may be formed of the same material. For example, the second high concentration doped region 128 may be a region in which the first conductive type dopant is doped into the second semiconductor 124 at a high concentration. The second high concentration doped region 128 may be spaced from the optical modulator 102. In this case, a portion of the second recess 106 between the second high concentration doped region 128 and the optical modulator 102 may be a portion at which the second semiconductor 124 extends.

The top surfaces of the first and second recesses 104 and 106 may be flat. The top surfaces of the first and second recesses 104 and 106 may have the same height. The top surfaces of the first and second recesses 104 and 106 may be parallel to the top surface of the substrate 100.

An oxide layer 110 may be disposed between the substrate 100 and the optical modulator 102. The oxide layer 110 may be disposed between the substrate 100 and the recesses 104 and 106. The oxide layer 110 may be disposed on the entire top surface of the substrate 100. The oxide layer 110 may be formed of a material having a refractive index different from that of the optical modulator 102.

For example, the oxide layer may include a silicon oxide layer. The oxide layer 110 may include a buried oxide layer of the SOI substrate. On the other hand, oxygen may be ion-implanted into a predetermined depth of a bulk semiconductor substrate using ion implantation to form the oxide layer 110. The oxygen ion implantation may be selectively performed on a portion at which an optical waveguide is formed. When the substrate is formed of silicon and the oxide layer 110 includes a silicon oxide layer, a vertical concentration of the silicon oxide layer may have a Gaussian distribution.

The electro-optic device 150 may have a light receiving surface 161 and a light emission surface 162. The light receiving surface 161 may face the light emission surface 162. The light receiving surface 161 and the light emission surface 162 may be parallel to each other. The receiving surface 161 and the light emission surface 162 may be perpendicular to both sidewalls of the optical modulator 102. A first signal 10 may be incident into the electro-optic device 150 through the light receiving surface 161. The first signal 10 may proceed in the first direction. A second signal 20 may be emitted through the light emission surface 162. The second signal 20 may proceed in the first direction.

The first signal 10 may have a phase different from that of the second signal 20. A phase difference between the first signal 10 and the second signal 20 may be adjusted by a density variation of carriers (e.g., electrons or holes) within the optical modulator 102 according to a thickness variation of the first depletion layer 142 of the optical modulator 102. A phase difference between the first signal 10 and the second signal 20 may be adjusted by a reverse bias voltage applied to the first semiconductor 122 and the third semiconductor 132, which form the first depletion layer 142.

As described above, when the electro-optic device 150 according to an embodiment of the present invention is operated, the reverse bias voltage may be applied between the first semiconductor 122 and the third semiconductor 132, which are adjacent to the first depletion layer 142. For example, when the first conductive type is the N-type and the second conductive type is the P-type, a voltage applied to the first semiconductor 122 may be greater than that of the third semiconductor 132. As a result, a width of the first depletion layer 142 may be widened, and a concentration of the carriers (e.g., the electrons or holes) within the optical modulator 102 may be reduced. As the concentration of the carriers is reduced, the phase of the optical signal passing through the optical modulator 102 may be modulated.

The reverse bias voltage may be generated by voltages applied to the first high concentration doped region 126 and the second high concentration doped region 128 when the electro-optic device 150 is operated. For example, the voltage applied to the first high concentration doped region 126 may be greater than that applied to the second high concentration doped region 128. Also, the first conductive type may be the N-type, and the second conductive type may be the P-type. In this case, the reverse bias voltage may be generated between the first semiconductor 122 and the third semiconductor 132, and a forward voltage may be generated between the second semiconductor 124 and the third semiconductor 132. As a result, the width of the first depletion layer 142 may be varied, and the phase of the optical signal passing through the optical modulator 102 may be modulated.

The first depletion layer 142 between the first semiconductor 122 and the third semiconductor 132 and the second depletion layer 144 between third semiconductor 132 and the second semiconductor 124 may constitute a PN junction capacitor connected in series. Thus, when compared that an optical modulator has a PN single junction, the depletion capacitance of the optical modulator 102 may be reduced, and the optical modulator 102 may be optimized for a high-speed operation.

Also, as a difference of the voltages applied to the first high concentration doped region 126 and the second high concentration doped region 128 gradually decreases, the depletion capacitances due to the first high concentration doped region 126 and the second high concentration doped region 128 may be similar to each other. In this case, a difference between the entire depletion capacitance of the optical modulator 150 and the depletion capacitance of the optical modulator having the PN single junction may be maximized.

An intensity of the first signal 10 may be different from that of the second signal 20. For example, when the optical modulator 102 absorbs a portion of the first signal 10, the intensity of the second signal 20 may be less than that of the first signal 10. The intensity of the second signal 20 may be adjusted according to a light absorption of the optical modulator 102. The light absorption of the optical modulator 102 may be adjusted by the density variation of the carriers (e.g., the electrons or holes) within the optical modulator 102 according to the thickness variation of the first depletion layer 142 of the optical modulator 102. An intensity difference between the first signal 10 and the second signal 20 may be adjusted by the reverse bias voltage applied to the first semiconductor 122 and the third semiconductor 132, which form the first depletion layer 142.

The light receiving surface 161 and the light emission surface 162 of the electro-optic device 150 may be connected to grating couplers 171 and 172, respectively. The light receiving surface 161 may be connected to the first grating coupler 171. The first grating coupler 171 may include an input transmission region and an input diffraction grating. The input diffraction grating may be disposed on a surface of the input transmission region. The input transmission region may be formed of a semiconductor material. A first optical fiber 181 may be disposed above the first grating coupler 171. An optical signal irradiated from the first optical fiber 181 may be provided into the input transmission region via the input diffraction grating. Due to the input diffraction grating, the optical signal within the input transmission region may be inputted into the electro-optic device 150 in a direction parallel to the top surface of the substrate 100.

The second grating coupler 172 may be connected to the light emission surface 162 of the electro-optic device 150. The second grating coupler 172 may include an output transmission region and an output diffraction grating. The output diffraction grating may be disposed on a top surface of the output transmission region. The output transmission region may be formed of a semiconductor material. A second optical fiber 182 may be disposed above the second grating coupler 172. An optical signal in which a phase thereof is modulated by transmitting the electro-optic device 150 may be supplied into the second optical fiber 182 via the output transmission region and the output diffraction grating. The optical signal supplied into the second optical fiber 182 may be supplied to other semiconductor chips and/or other electronic media.

A peripheral region B according to an embodiment of the present invention will now be described.

A semiconductor device 350 may be disposed in the peripheral region B of the substrate 100. The semiconductor device 350 may be a switching device. The semiconductor device 350 may include a gate dielectric 352 on the substrate 100. The semiconductor device 350 may include a gate electrode 354 on the gate dielectric 352. The gate dielectric 352 may include at least one of a silicon oxynitride layer, a silicon nitride layer, a silicon oxide layer, and a metal oxide layer. The gate electrode 354 may include at least one of a doped polysilicon layer, a metal layer, and a metal nitride layer.

A modified example of an electro-optic device according an embodiment of the present invention will now be described. FIG. 2B is a sectional view illustrating a modified example of an electro-optic device according to an embodiment of the present invention. Explanation relating to the same configuration as the embodiment of FIG. 2A may be omitted.

Referring to FIG. 2B, the whole of at least one of the first recess 104 and the second recess 106 may be the first high concentration doped region 126 and the second high concentration doped region 128. For example, the whole of the first recess 104 may be the first high concentration doped region 126. In this case, the optical modulator 102 and the first recess 104 may be separated from each other by an interface between the first high concentration doped region 126 and the first semiconductor 122. On the other hand, the whole of the second recess 106 may be the second high concentration doped region 128. In this case, the optical modulator 102 and the second recess 106 may be separated from each other by an interface between the second high concentration doped region 128 and the second semiconductor 124.

A modified example of an electro-optic device according to an embodiment of the present invention will now be described. FIG. 2C is a sectional view illustrating a modified example of an electro-optic device according to an embodiment of the present invention. Explanation relating to the same configuration as the embodiment of FIG. 2A may be omitted.

Referring to FIG. 2C, at least one of the first high concentration doped region 126 and the second high concentration doped region 128 may extend to the optical modulator 102. For example, when the first high concentration doped region 126 extends to the optical modulator 102, a portion of the optical modulator 102 adjacent to the first recess 104 may include the first high concentration doped region 126. On the other hand, when the second high concentration doped region 128 extends to the optical modulator 102, a portion of the optical modulator 102 adjacent to the second recess 106 may include the second high concentration doped region 128.

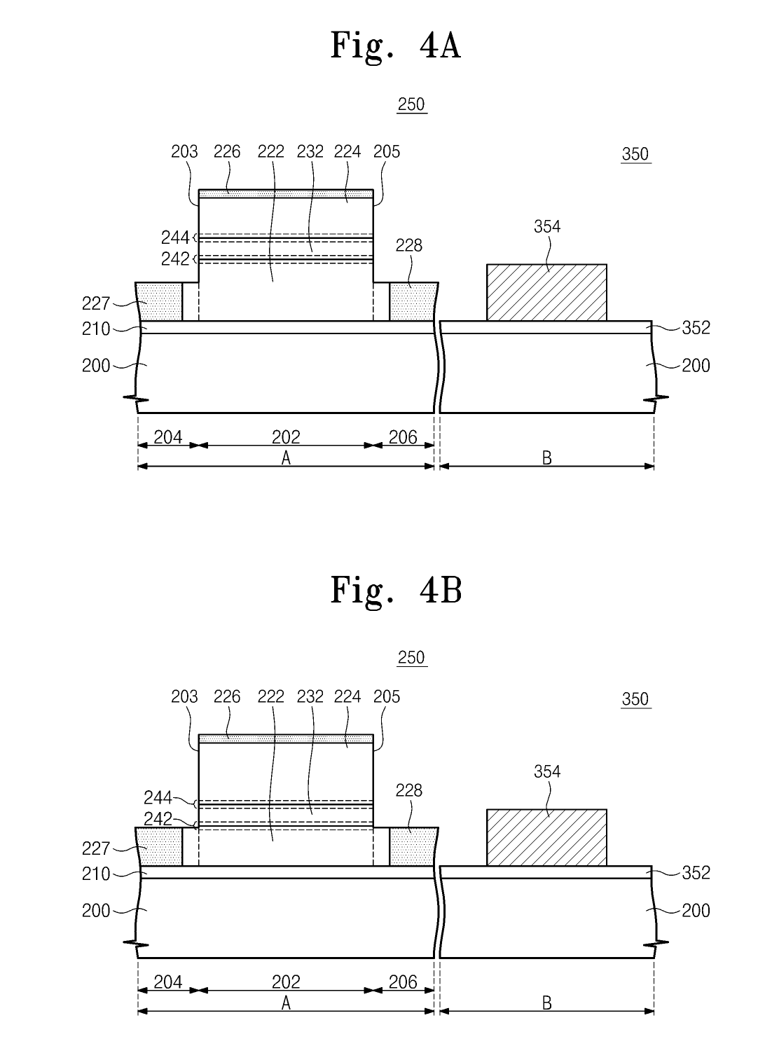

An electro-optic device according to another embodiment of the present invention will now be described. FIG. 4A is a plan view for explaining an electro-optic device according to another embodiment of the present invention. A sectional view taken along line I-I′ of FIG. 1 illustrates an electro-optic region A of FIG. 4A, and a peripheral region B of FIG. 4A may be a peripheral circuit region spaced from the electro-optic region A.

Referring to FIGS. 1 and 4, a substrate 200 is prepared. The substrate 200 may include a silicon substrate or a SOI substrate. The substrate 200 may include an electro-optic region A and a peripheral region B. An electro-optic device 250 may be disposed in the electro-optic region A. A semiconductor device 350 may be disposed in the peripheral region B.

The electro-optic region A according to another embodiment of the present invention will now be described.

The electro-optic device 250 may be disposed in the electro-optic region A of the substrate 200. The electro-optic device 250 may extend in a first direction on the substrate 200. The first direction may be parallel to a top surface of the substrate 200. The electro-optic device 250 may include optical modulator 202 and first and second recesses 204 and 206 connected to both sidewalls of the optical modulator 202. The optical modulator 202 may include a first sidewall 203 and a second sidewall 205, which face each other. The first recess 204 may be connected to the first sidewall 203, and the second recess 206 may be connected to the second sidewall 205. The optical modulator 202 may have a flat top surface. The top surface of the optical modulator 202 may be parallel to the top surface of the substrate 200. The optical modulator 202 may be a region through which an optical signal passes. The optical signal may proceed in first direction. Both sidewalls of the optical modulator 202 may extend from a top surface of the first recess 204 and a top surface of the second recess 206, respectively. The first and second recesses 204 and 206 may have the top surfaces lower than that of the optical modulator 202.

The optical modulator 202 may include a first semiconductor 222 disposed on the substrate 200, a second semiconductor 224, and a third semiconductor 232 disposed between the first semiconductor 222 and the second semiconductor 224. The first semiconductor 222 and the second semiconductor 224 may be spaced from each other with the third semiconductor 232 therebetween. The first semiconductor 222, the second semiconductor 224, and the third semiconductor 232 may be sequentially stacked on the substrate 200. The third semiconductor 232 may be spaced from the substrate 200 with the first semiconductor 222 therebetween.

A junction surface between the first semiconductor 222 and the third semiconductor 232 may be parallel to the top surface of the substrate 200. A junction surface between the second semiconductor 224 and the third semiconductor 232 may be parallel to the top surface of the substrate 200.

The first and second semiconductors 222 and 224 may include regions doped with a first conductive type dopant, respectively. The third semiconductor 232 may include a region doped with a second conductive type dopant different from the first conductive type dopant. The first conductive type and the second conductive type may be different from each other. For example, the first conductive type may be an N-type, and the second conductive type may be a P-type. On the other hand, the first conductive type may be a P-type, and the second conductive type may be an N-type.

A first high concentration doped region 226 may be defined on the second semiconductor 224. The first high concentration doped region 226 may be a region doped with the first conductive type dopant at a doping concentration greater than that of the second semiconductor 224. For example, the first high concentration doped region 226 may be a region in which the first conductive type dopant is doped into the second semiconductor 224 at a high concentration.

First and second depletion layers 242 and 244 may be formed by a junction of the first semiconductor 222 and the third semiconductor 232 and a junction of the second semiconductor 224 and the third semiconductor 232, respectively. The first and second depletion layers 242 and 244 may be respectively formed along the junction surface between the first semiconductor 222 and the third semiconductor 232 and the junction surface between the second semiconductor 224 and the third semiconductor 232. The first and second depletion layers 242 and 244 may be parallel to the top surface of the substrate 200.

A thickness of the first semiconductor 222 included in the optical modulator 202 may be equal to the sum of a thickness of the third semiconductor 232, a thickness of the second semiconductor 224, and a thickness of the first high concentration doped region 226.

The optical modulator 202 may have a top surface and a bottom surface adjacent to the substrate 200. The bottom surface of the optical modulator 202 may be a bottom surface of the first semiconductor 222 within the optical modulator 202. The top surface of the optical modulator 202 may be a top surface of the first high concentration doped region 226. When the junction surfaces between first, second, and third semiconductors 222, 224, and 232 are parallel to the top surface of the substrate 200, a distance between the first depletion layer 242 and the bottom surface of the optical modulator 202 may be equal to that from the first depletion layer 242 to the top surface of the optical modulator 202. The first depletion layer 242 may be disposed at a middle portion between the top surface and the bottom surface of the optical modulator 202.

The top surfaces of the first and second recesses 204 and 206 may be flat. The top surfaces of the first and second recesses 204 and 206 may have the same height. The top surfaces of the first and second recesses 204 and 206 may be parallel to the top surface of the substrate 200.

The first recess 204 may include a second high concentration doped region 227. The second high concentration doped region 227 may be a region doped with the first conductive type dopant at a doping concentration greater than that of the first semiconductor 222. The second high concentration doped region 227 and the first semiconductor 222 may be formed of the same material. For example, the second high concentration doped region 227 may be a region in which the first conductive type dopant is doped into the first semiconductor 222 at a high concentration. The second high concentration doped region 227 may be spaced from the optical modulator 202. In this case, a portion of the first recess 204 between the second high concentration doped region 227 and the optical modulator 202 may be a portion at which the first semiconductor 222 extends.

The second recess 206 may include a third high concentration doped region 228. The third high concentration doped region 228 may be a region doped with the first conductive type dopant at a doping concentration greater than that of the first semiconductor 222. The third high concentration doped region 228 and the first semiconductor 222 may be formed of the same material. For example, the third high concentration doped region 228 may be a region in which the first conductive type dopant is doped into the first semiconductor 222 at a high concentration. The third high concentration doped region 228 may be spaced from the optical modulator 202. In this case, a portion of the second recess 206 between the third high concentration doped region 228 and the optical modulator 202 may be a portion at which the first semiconductor 222 extends.

When the electro-optic device 250 according to another embodiment of the present invention is operated, a reverse bias voltage may be applied between the first semiconductor 222 and the third semiconductor 232, which are adjacent to the first depletion layer 242. For example, when the first conductive type is the N-type and the second conductive type is the P-type, a voltage applied to the first semiconductor 222 may be greater than that of the third semiconductor 232. As a result, a thickness of the first depletion layer 242 may be thicker, and a density of carriers within the optical modulator 202 may be reduced to modulate a phase of the optical signal passing through the optical modulator 202.

The reverse bias voltage may be generated by voltages applied between the first high concentration doped region 226 and the second and third high concentration doped regions 227 and 228 when the electro-optic device 250 is operated. For example, a voltage V1 may be applied to the first high concentration doped region 226, and voltages V2 greater than the voltage V1 may be respectively applied to the second and third high concentration doped regions 227 and 228. The first conductive type may be the N-type, and the second conductive type may be the P-type. In this case, the reverse bias voltage may be generated between the first semiconductor 222 and the third semiconductor 232, and a forward voltage may be generated between the second semiconductor 224 and the third semiconductor 232. As a result, the thickness of the first depletion layer 242 may increase. An increasing amount of the thickness of the first depletion layer 242 may be adjusted by a difference between the voltage V1 and the voltage V2.

An oxide layer 220 may be disposed between the substrate 200 and the optical modulator 202. The oxide layer 220 may be disposed between the substrate 200 and the recesses 204 and 206. The oxide layer may be the oxide layer 100 described with reference to FIG. 2A.

The electro-optic device 250 may have a light receiving surface 161 and a light emission surface 162, which are described with reference to FIG. 2A. A phase and intensity of an incident signal of the electro-optic device 250 may be adjusted as described with reference to FIG. 2A. The first depletion layer 242 and the second depletion layer 244 may constitute a PN junction capacitor connected in series as described with referent to FIG. 2A. The electro-optic device 250 may be connected to the grating couplers 171 and 172 as described with reference to FIGS. 1 and 3.

A peripheral region B according to an embodiment of the present invention will now be described.

The semiconductor device 350 described with reference to FIG. 2A may be disposed in the peripheral region B according to another embodiment of the present invention.

A modified example of an electro-optic device according another embodiment of the present invention will now be described. FIG. 4B is a sectional view illustrating a modified example of an electro-optic device according to another embodiment of the present invention. Explanation relating to the same configuration as the embodiment of FIG. 4A may be omitted.

The first semiconductor 222 may have a thickness greater than those of the first and second recesses 204 and 206. A distance from the junction surface between the second semiconductor 224 and the third semiconductor 232 to the top surface of the optical modulator 202 may be equal to that from the junction surface between the second semiconductor 224 and the third semiconductor 232 to the bottom surface of the optical modulator 202.

A reverse bias voltage may be applied between the second semiconductor 224 and the third semiconductor 232, which form the second depletion layer 244. For example, when a voltage applied to the first high concentration doped region 226 is greater those that applied to the second high concentration doped region 227 and the third high concentration doped region 228, the first conductive type is the N-type, and the second conductive type is the P-type, the reverse bias voltage may be generated between the second semiconductor 224 and the third semiconductor 232, which form the second depletion layer 244. A phase of the optical signal may be modulated due to a thickness variation occurring by the reverse bias voltage.

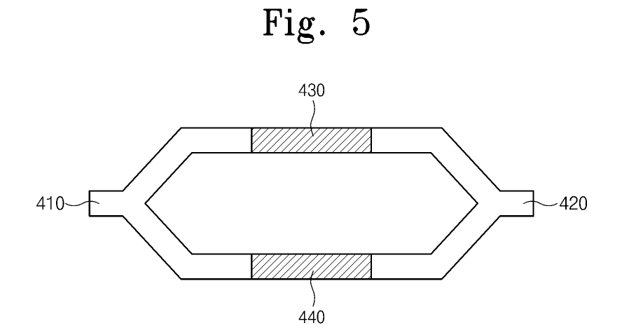

An application example of the electro-optic device according to the embodiments of the present invention will now be described. FIG. 5 is a view illustrating an application example of the electro-optic device according to the embodiments of the present invention.

Referring to FIG. 5, a mach-zehnder interferometer 400 may include an input Y-branch 410, a first electro-optic device 430, an output Y-branch 420, and a second electro-optic device 440. One of the first electro-optic device 430 and the second electro-optic device 440 may include the electro-optic device according to the embodiment of the present invention. On the other hand, the electro-optic devices 430 and 440 may include the electro-optic device according to the embodiments of the present invention.

The first electro-optic device 430 and the second electro-optic device 440 may be connected between two arms of the input Y-branch 410 and two arms of the output Y-branch 420.

An optical signal may be incident into the input Y-branch 410. The optical signal incident into the input Y-branch 410 may be divided at a branch point of the input Y-branch 410. The divided optical signals may be incident into the first electro-optic device 430 and the second electro-optic device 440, respectively. The optical signal incident into first electro-optic device 430 and the second electro-optic device 440 pass through the first electro-optic device 430 and the second electro-optic device 440, and thus, phases thereof may be varied. The optical signals passing through the electro-optic devices 430 and 440 may get together at the output Y-branch 420. When the optical signals get together at the output Y-branch 420, the optical signals may destructively interfere or constructively interfere with each other. The occurrence of the destructive interference or constructive interference may be affected by phase variation degrees of the optical signals passing through the electro-optic devices 430 and 440. The phase variation degrees may be affected by the intensities of the reverse bias voltages applied to the electro-optic devices 430 and 440.

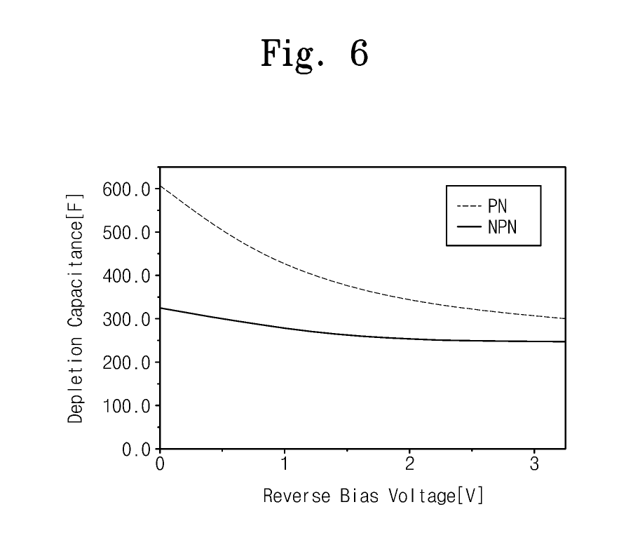

A variation characteristic of a depletion capacitance of an optical modulator according to the embodiments of the present invention will now be described. FIG. 6 is a graph illustrating a variation characteristic of a depletion capacitance of an optical modulator according to the embodiments of the present invention.

Referring to FIG. 6, the graph illustrates a variation according to a revere bias voltage of a depletion capacitance of an optical modulator including P-type and N-type semiconductor layers and a depletion capacitance of an optical modulator including N-type, P-type, and N-type semiconductor layers. A horizontal axis represents an intensity of the reverse bias voltage, and a vertical axis represents a capacitance (dot line) of a PN semiconductor layer and a capacitance (solid line) of an NPN semiconductor layer.

In this graph, the N-type semiconductor layer has a doping concentration of about 10¹⁹ cm⁻³, and the P-type semiconductor layer has a doping concentration of about 10¹⁸ cm⁻³. As shown in graph, it is seen that the NPN semiconductor layer has a capacitance less than that of the PN semiconductor layer. As the reverse bias voltage gradually decreases in intensity, a difference between the depletion capacitance of the NPN semiconductor layer and the depletion capacitance of the PN semiconductor layer significantly increases.

The electro-optic device according to the embodiments of the present invention may be integrated on the same substrate together with an electrical device or an optical device to realize a small-sized silicon integrated circuit. For example, the electrical device such as a CMOS (complementary metal oxide semiconductor), a bipolar transistor, a P-I-N diode, or a diode may be integrated together with the electro-optic device 150. Also, the optical device such as a multiplexer or a photodiode may be integrated on the substrate together with the electro-optic device. The electrical device or the optical device described above may be integrated on the silicon substrate together with the electro-optic device according to the embodiments of the present invention.

As described above, since the electro-optic device includes the plurality of depletion layers, the capacitance of the electro-optic device can be reduced, and the electro-optic device can be operated at a high speed. Therefore, the electro-optic device optimized for friendly environment and low power consumption can be provided.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An electro-optic device comprising:
a substrate;
a optical modulator disposed on the substrate, the optical modulator comprising a first conductive type first semiconductor, a first conductive type second semiconductor, and a second conductive type third semiconductor disposed between the first semiconductor and the second semiconductor; and
first and second recesses connected to both sidewalls of the optical modulator, the first and second recesses having top surfaces lower than a top surface of the optical modulator,
wherein the optical modulator comprises a first depletion layer formed by a junction of the first semiconductor and the third semiconductor and a second depletion layer formed by a junction of the second semiconductor and the third semiconductor, and the first conductive type and the second conductive type are different from each other.

2. The electro-optic device of claim 1, wherein a reverse bias voltage is applied to any one of the first and second depletion layers during the operation.

3. The electro-optic device of claim 2, wherein the first recess and the second recess comprise a first high concentration doped region and a second high concentration doped region, which have a concentration greater than those of the first semiconductor and the second semiconductor, respectively, and
the reverse bias voltage is generated by a voltage applied between the first high concentration doped region and the second high concentration doped region during the operation.

4. The electro-optic device of claim 3, wherein the first high concentration doped region and the second high concentration doped region are laterally spaced from both sidewalls of the optical modulator.

5. The electro-optic device of claim 4, wherein the optical modulator has a light receiving surface through which a first optical signal is incident and a light emission surface through which a second optical signal is emitted,
wherein a phase of the second optical signal is adjusted by the reverse bias voltage difference.

6. The electro-optic device of claim 5, further comprising a grating coupler connected to any one of the light receiving surface and the light emission surface of the optical modulator.

7. The electro-optic device of claim 2, wherein a light absorption of the optical modulator is adjusted by the reverse bias voltage difference.

8. The electro-optic device of claim 1, further comprising an oxide layer disposed between the substrate and the optical modulator.

9. The electro-optic device of claim 8, wherein the oxide layer is formed by selectively injecting oxygen ions into a portion at which an optical waveguide is formed on the substrate.

10. The electro-optic device of claim 1, wherein the substrate has a peripheral region laterally spaced from an electro-optic region in which the optical modulator is disposed,
wherein the electro-optic device further comprises:
a gate dielectric in the peripheral region of the substrate; and
a gate electrode disposed on the gate dielectric.

11. The electro-optic device of claim 1, wherein a first junction surface between the first semiconductor and the third semiconductor and a second junction surface between the second semiconductor and the third semiconductor are non-parallel to a top surface of the substrate.

12. The electro-optic device of claim 11, wherein the optical modulator has a first sidewall and a second sidewall, which face each other,
wherein the junction surfaces are perpendicular to the top surface of the substrate, and
a distance between any one of the junction surfaces and the first sidewall is equal to that between any one of the junction surfaces and the second sidewall.

13. The electro-optic device of claim 12, wherein a reverse bias voltage is applied between the semiconductors, which form the any one junction surface, during the operation.

14. The electro-optic device of claim 1, wherein the first semiconductor, the second semiconductor, and the third semiconductor are sequentially stacked on the substrate, and a first junction surface between the first semiconductor and the third semiconductor and a second junction surface between the second semiconductor and the third semiconductor are parallel to a top surface of the substrate.

15. The electro-optic device of claim 14, wherein the optical modulator further comprises the first conductive type high concentration doped region disposed on the second semiconductor and having a concentration greater than that of the second semiconductor.

16. The electro-optic device of claim 15, wherein the optical modulator has a top surface and a bottom surface,
wherein a distance between any one of the junction surfaces and the top surface is equal to that between any one of the junction surfaces and the bottom surface.

17. The electro-optic device of claim 16, wherein a reverse bias voltage is applied between the semiconductors, which form the any one junction surface, during the operation.

18. An electro-optic device comprising:
an input Y-branch comprising an input terminal, a first optical waveguide connected to the input terminal, and a second optical waveguide spaced from the first optical waveguide and connected to the input terminal; and
an output Y-branch comprising the first optical waveguide, the second optical waveguide, and an output terminal connected to the first optical waveguide and the second optical waveguide,
wherein at least one of the first optical waveguide and the second optical waveguide comprises:
a substrate;
a optical modulator disposed on the substrate, the optical modulator comprising a first conductive type first semiconductor, a first conductive type second semiconductor, and a second conductive type third semiconductor disposed between the first semiconductor and the second semiconductor; and
first and second recesses connected to both sidewalls of the optical modulator, the first and second recesses having top surfaces lower than a top surface of the optical modulator,
wherein the optical modulator comprises a first depletion layer formed by a junction of the first semiconductor and the third semiconductor and a second depletion layer formed by a junction of the second semiconductor and the third semiconductor, and the first conductive type and the second conductive type are different from each other.

19. The electro-optic device of claim 16, wherein a difference between phases of an input optical signal inputted into the input terminal and an output optical signal outputted from the output terminal is adjusted by a thickness variation of any one depletion layer of the first depletion layer and the second depletion layer.
